(19) United States
(12) Patent Application Publication
(10) Pub. No.: US 2020/0166562 A1
(43) Pub. Date: May 28, 2020

(54) INSPECTION APPARATUS, TEMPERATURE CONTROL DEVICE AND TEMPERATURE CONTROL METHOD

(71) Applicant: TOKYO ELECTRON LIMITED, Tokyo (JP)

(72) Inventor: Yuki ISHIDA, Nirasaki City (JP)

(21) Appl. No.: 16/694,120

(22) Filed: Nov. 25, 2019

(30) Foreign Application Priority Data
Nov. 27, 2018 (JP) 2018-221602

(51) Int. Cl. G01R 31/26; G01R 31/28

(52) U.S. Cl. CPC G01R 31/2601; G01R 31/2849

(57) ABSTRACT

An inspection apparatus for inspecting electrical characteristics of a plurality of devices formed on an inspection object, includes a stage configured to mount the inspection object, a temperature detector configured to detect a temperature of the stage, a heat source provided separately from the stage, a cooler configured to cool the stage, and a temperature controller configured to control the heat source and the cooler based on the temperature of the stage detected by the temperature detector.

### CROSS-REFERENCE TO RELATED APPLICATION

This application is based upon and claims the benefit of priority from Japanese Patent Application No. 2018-221602, filed on Nov. 27, 2018, the entire contents of which are incorporated herein by reference.

### TECHNICAL FIELD

The present disclosure relates to an inspection apparatus, a temperature control device and a temperature control method.

### BACKGROUND

In a semiconductor device manufacturing process, the electrical characteristics of a plurality of devices formed on a substrate are inspected using an inspection apparatus. The inspection apparatus includes a stage for mounting the substrate. The stage is controlled to a predetermined temperature by heating with a heater and cooling with a cooling means.

### PRIOR ART DOCUMENT

### Patent Document

Patent Document 1: Japanese Patent Application Publication H10-135315

### SUMMARY

According to one embodiment of the present disclosure, there is provided an inspection apparatus for inspecting electrical characteristics of a plurality of devices formed on an inspection object, includes a stage configured to mount the inspection object, a temperature detector configured to detect a temperature of the stage, a heat source provided separately from the stage, a cooler configured to cool the stage, and a temperature controller configured to control the heat source and the cooler based on the temperature of the stage detected by the temperature detector.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a view showing a configuration example of an inspection apparatus.

FIG. 2 is a plan view of the inspection apparatus shown in FIG. 1.

FIG. 3 is a view showing a configuration example of a wafer transfer mechanism of the inspection apparatus shown in FIG. 1.

FIG. 4 is a view showing a configuration example of a temperature control system of the inspection apparatus shown in FIG. 1.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Hereinafter, a non-limiting exemplary embodiment of the present disclosure will be described with reference to the accompanying drawings. Throughout the attached drawings, the same or corresponding members or parts are denoted by the same or corresponding reference numerals, and the redundant description thereof is omitted.

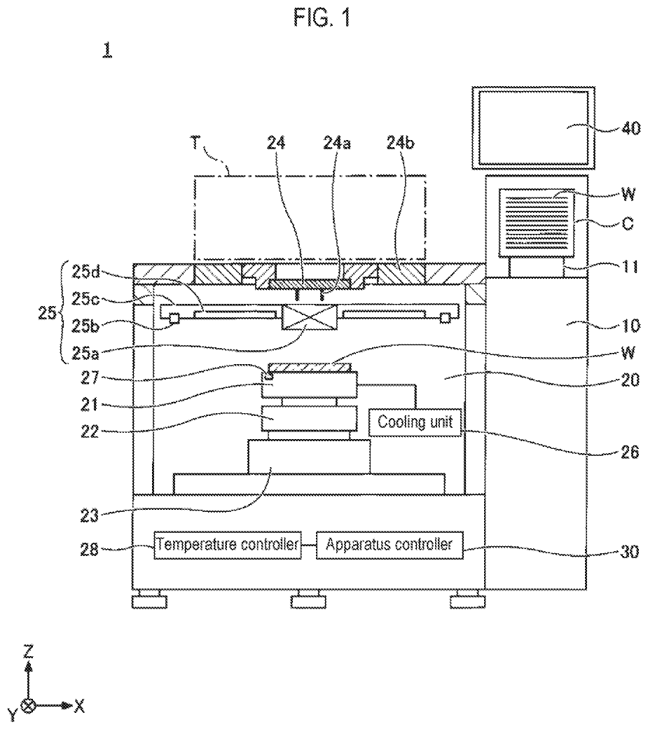

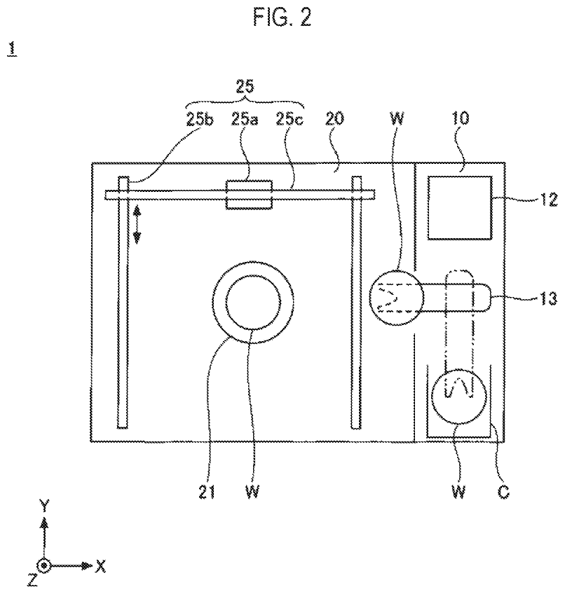

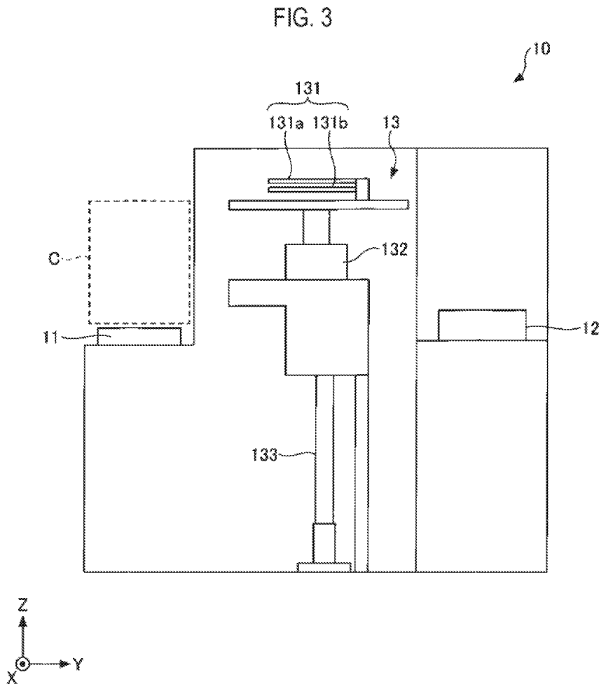

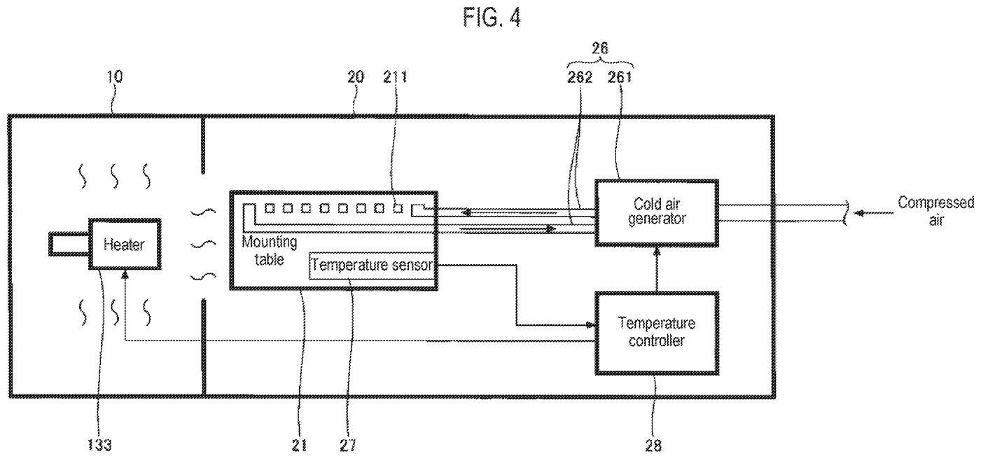

The inspection apparatus will be described with reference to FIGS. 1 to 4. FIG. 1 is a view showing a configuration example of the inspection apparatus. FIG. 2 is a plan view of the inspection apparatus shown in FIG. 1. FIG. 3 is a view showing a configuration example of a wafer transfer mechanism of the inspection apparatus shown in FIG. 1. FIG. 4 is a view showing a configuration example of a temperature control system of the inspection apparatus shown in FIG. 1.

The inspection apparatus 1 includes a loader part 10, an inspection part 20 and a apparatus controller 30. The inspection apparatus 1 transfers a semiconductor wafer (hereinafter referred to as “wafer W”) as an inspection object from the loader part 10 to the inspection part 20 under the control of the apparatus controller 30. The inspection apparatus 1 inspects various electrical characteristics by applying an electrical signal to a DUT (Device under Test) formed on the wafer W.

The loader part 10 includes a load port 11, an aligner 12 and a wafer transfer mechanism 13.

The load port 11 mounts a cassette C containing wafers W. The cassette C is, for example, a FOUP (Front Opening Unified Pod).

The aligner 12 aligns the wafer W with reference to a cutout such as an orientation flat, a notch or the like formed on the wafer W.

The wafer transfer mechanism 13 transfers the wafer W between the cassette C placed on the load port 11, the aligner 12 and the stage 21 provided in the inspection part 20 described later. The wafer transfer mechanism 13 includes an arm unit 131, a rotary drive mechanism 132 and a vertical drive mechanism 133.

The arm unit 131 includes arms 131a and 131b provided in two upper and lower stages and capable of independently moving in the horizontal direction. Each of the arms 131a and 131b holds a wafer W.

The rotary drive mechanism 132 is provided below the arm unit 131 to rotationally drive the arm unit 131. The rotary drive mechanism 132 includes, for example, a stepping motor.

The vertical drive mechanism 133 is provided below the rotary drive mechanism 132 vertically drive the arm unit 131 and the rotary drive mechanism 132. The vertical drive mechanism 133 includes, for example, a stepping motor. The wafer transfer mechanism 13 is not limited to the form shown in FIG. 3 but may have, for example, a form including an articulated arm, a vertical drive mechanism and the like.

In the loader part 10, first, the wafer transfer mechanism 13 transfers the wafer W accommodated in the cassette C to the aligner 12. Subsequently, the aligner 12 aligns the wafer W. Then, the wafer transfer mechanism 13 transfers the aligned wafer W from the aligner 12 to the stage 21 provided in the inspection part 20.

The inspection part 20 is disposed adjacent to the loader part 10. The inspection part 20 includes a stage 21, an elevating mechanism 22, an XY stage 23, a probe card 24, an alignment mechanism 25, a cooling unit 26, a temperature sensor 27 and a temperature controller 28.

The stage 21 mounts the wafer W on the upper surface thereof. The stage 21 includes, for example, a vacuum chuck or an electrostatic chuck. The stage 21 has a flow path 211. A low temperature air is supplied from the cooling unit 26 to the flow path 211. Thus, the stage 21 is cooled.

The elevating mechanism 22 is provided below the stage 21 to vertically move the stage 21 with respect to the XY stage 23. The elevating mechanism 22 includes, for example, a stepping motor.

The XY stage 23 is provided below the elevating mechanism 22 to move the stage 21 and the elevating mechanism 22 in two axis directions (the X direction and the Y direction in the drawings). The XY stage 23 is fixed to the bottom of the inspection part 20. The XY stage 23 includes, for example, a stepping motor.

The probe card 24 is disposed above the stage 21. A plurality of probes 24a is formed in the probe card 24 on portions near the stage 21. The probe card 24 is detachably attached to a head plate 24b. A tester (not shown) is connected to the probe card 24 via a test head T.

The alignment mechanism 25 includes a camera 25a, guide rails 25b, an alignment bridge 25c and a light source 25d. The camera 25a is attached to the center of the alignment bridge 25c so as to face downward. The camera 25a captures an image of the stage 21, the wafer W and the like. The camera 25a is, for example, a CCD camera or a CMOS camera. The guide rails 25b support the alignment bridge 25c so as to be movable in the horizontal direction (Y direction the drawings). The alignment bridge 25c is supported by a pair of left and right guide rails 25b and is moved in the horizontal direction (Y direction in the drawings) along the guide rails 25b. As a result, the camera 25a moves between a standby position and a position immediately below the center of the probe card 24 (hereinafter referred to as “probe center”) via the alignment bridge 25c. During alignment, the camera 25a located at the probe center captures an image of the electrode pads of the wafer W on the stage 21 from above while the stage 21 moves in the XY direction. The camera 25a performs image processing and displays the captured image on a display device 40. The light source 25d is provided below the alignment bridge 25c and irradiates the stage 21 with light, The light source 25d is, for example, an LED light source in which a large number of light emitting diodes (LEDs) are arranged.

The cooling unit 26 includes a cold air generator 261 and a pipe 262. The cold air generator 261 is, for example, a vortex cooler that makes use of a vortex effect. The vortex cooler has a vortex tube that generates a low-temperature air when supplied with a compressed air. The pipe 262 circulates the low-temperature air, which is generated by the cold air generator 261, between the cold air generator 261 and the flow path 211 in the stage 21.

The temperature sensor 27 detects the temperature of the stage 21. The temperature sensor 27 is, for example, a thermocouple embedded in the stage 21.

The temperature controller 28 is provided below the stage 21. The temperature controller 28 is, for example, a computer. The temperature controller 28 executes a temperature control method including a step of detecting the temperature of the stage 21 by the temperature sensor 27 and a step of controlling the standby power of the vertical drive mechanism 133 and the cooling unit 26 based on the temperature of the stage 21 detected by the temperature sensor 27.

When the temperature of the stage 21 is lower than a target temperature, the temperature controller 28 increases the standby power of the vertical drive mechanism 133. Accordingly, the amount of heat generated by the standby power of the vertical drive mechanism 133 is increased, and the heat is transmitted from the loader part 10 to the inspection part 20. For this reason, the temperature of the stage 21 rises. The target temperature is, for example, 20 to 30 degrees C. When the drive mechanism is a stepping motor, the standby power is the power generated by a holding current that holds the rotation angle of the stepping motor. Furthermore, the temperature controller 28 may finely adjust the temperature of the stage 21 by controlling the cooling unit 26. In the cooling unit 26, the cooling capacity can be controlled by adjusting the pressure, temperature and air volume of the compressed air supplied to the vortex tube, and adjusting the valve existing on the hot air side of the vortex tube.

For example, the cooling capacity can be increased by increasing the pressure of the compressed air supplied to the vortex tube. The cooling capacity can also be increased by increasing the temperature of the compressed air supplied to the vortex tube. The cooling capacity can also be increased by increasing the amount of the compressed air supplied to the vortex tube. On the other hand, for example, the cooling capacity can be lowered by reducing the pressure of the compressed air supplied to the vortex tube. The cooling capacity can also be lowered by reducing the temperature of the compressed air supplied to the vortex tube. The cooling capacity can also be lowered by reducing the amount of the compressed air supplied to the vortex tube.

When the temperature of the stage 21 is higher than the target temperature, the temperature controller 28 reduces the standby power of the vertical drive mechanism 133. As a result, the amount of heat generated by the standby power of the vertical drive mechanism 133 is reduced, and the heat transfer from the loader part 10 to the inspection part 20 is suppressed. For this reason, the temperature rise of the stage 21 is suppressed. In addition, the temperature controller 28 increases the cooling capacity of the cooling unit 26. As a result, the temperature of the stage 21 decreases and approaches the target temperature.

In the inspection part 20, first, the temperature controller 28 controls the standby power of the vertical drive mechanism 133 of the loader part 10 and the cooling unit 26 based on the temperature of the stage 21 detected by the temperature sensor 27, whereby the temperature of the stage 21 is adjusted to the target temperature. Subsequently, the alignment mechanists 25 aligns the electrode pads of a DUT formed on the wafer W on the stage 21 with the plurality of probes 24a of the probe card 24. Then, the elevating mechanism 22 raises the stage 21 to bring the plurality of probes 24a of the probe card 24 into contact with the corresponding electrode pads. Subsequently, the apparatus controller 30 applies an inspection signal from the tester to the DUT formed on the wafer W via the test head T and the plurality of probes 24a of the probe card 24, thereby inspecting the electric characteristics of the DUT.

The apparatus controller 30 is provided below the stage 21 to control the overall operation of the inspection apparatus 1. The CPU provided in the apparatus controller 30 executes a desired inspection according to the product type parameters stored in a memory such as ROM or RAM. The product type parameters may be stored in a semiconductor memory other than the hard disk, the ROM or the RAM. The product type parameters may be inserted into a predetermined position in a state in which they are recorded on a computer-readable recording medium such as a CD-ROM, a DVD or the like, and may be read therefrom.

As described above, according to the inspection apparatus 1, the temperature controller 28 adjusts the temperature of the stage 21 by controlling the standby power of the vertical drive mechanism 133 of the loader part 10 and the cooling unit 26. For this reason, it is not required that an electrical component for increasing the temperature, such as a heater or the like, be mounted on the inspection part 20. As a result, it is possible to reduce electrical noise generated when adjusting the temperature of the stage 21. Moreover, it is possible to reduce cost and power consumption.

Moreover, according to the inspection apparatus 1, the cooling unit 26 is a vortex cooler using a vortex effect. Therefore, the footprint can be reduced compared to using a chiller or the like. It may also be possible to use a chiller.

In the above-described embodiment, the vertical drive mechanism 133 is an example of a heat source, the temperature sensor 27 is an example of a temperature detection part, the cooling unit 26 is an example of a cooling part, and the temperature controller 28 is an example of a temperature control part. Furthermore, the vertical drive mechanism 133, the temperature sensor 27, the cooling unit 26, and the temperature controller 28 constitute a temperature control device.

It should be noted that the embodiment disclosed herein is illustrative and not restrictive at all respects. The above-described embodiment may be omitted, replaced and modified in various forms without departing from the scope and spirit of the appended claims.

In the above-described embodiment, the case where the cold air generator 261 is provided in the inspection part 20 has been described. However, the present disclosure is not limited thereto. The cold air generator 261 may be provided outside the inspection part 20,

Moreover, the above-described embodiment discloses an instance where heat generated by the standby power of the vertical drive mechanism 133 of the loader part 10 is utilized as a heat source. However, the present disclosure is not limited thereto. For example, the heat generated by the standby power of another drive mechanism of the loader part 10, such as the heat generated by the standby power of the rotary drive mechanism 132, may be used. Furthermore, for example, the heat generated by the standby power of the drive mechanism of the inspection part 20, such as the elevating mechanism 22, the XY stage 23, the alignment mechanism 25 or the like, may be used. Moreover, for example, the heat generated by the light source 25d of the inspection part 20 may be used. In addition, the heat generated by the computer such as the temperature controller 28 or the apparatus controller 30 may be used. When using the heat generated by the computer, the amount of heat generated can be increased by, for example, increasing the load on the computer. Furthermore, at least some of the heat generated by the standby power of the drive mechanism, the heat generated by the light source 25d and the heat generated by the temperature controller 28 may be used in combination.

In the above-described embodiment, the inspection apparatus 1 in which one inspection part is provided for one loader part has been described as an example. However, the present disclosure is not limited thereto. For example, it may be possible to adopt an inspection apparatus in which a plurality of inspection parts is provided with respect to one or more loader parts.

According to the present disclosure in some embodiments, it is possible to adjust the temperature of a stage while suppressing generation of electrical noise.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. An inspection apparatus for inspecting electrical characteristics of a plurality of devices formed on an inspection object, comprising:
a stage configured to mount the inspection object;
a temperature detector configured to detect a temperature of the stage;
a heat source provided separately from the stage;
a cooler configured to cool the stage; and
a temperature controller configured to control the heat source and the cooler based on the temperature of the stage detected by the temperature detector.

2. The inspection apparatus of claim 1, wherein the temperature controller is configured to increase a heat generation amount of the heat source when the temperature of the stage is lower than a target temperature.

3. The inspection apparatus of claim 2, wherein the temperature controller is configured to reduce a heat generation amount of the heat source when the temperature of the stage is higher than a target temperature.

4. The inspection apparatus of claim 3, wherein the heat source is a drive mechanism, and the heat generation amount is adjusted by a standby power of the drive mechanism.

5. The inspection apparatus of claim 4, wherein the drive mechanism is a stepping motor, and the standby power is power for maintaining a rotation angle of the stepping motor.

6. The inspection apparatus of claim 5, wherein the drive mechanism is provided in a loader part disposed adjacent to an inspection part in which the stage is provided.

7. The inspection apparatus of claim 6, wherein the target temperature is 20 to 30 degrees C.

8. The inspection apparatus of claim 7, wherein the cooler comprises a cold air generator configured to generate a low-temperature air using a vortex effect, and a pipe configured to supply the low-temperature air generated by the cold air generator into the stage.

9. The inspection apparatus of claim 8, wherein the temperature controller is configured to control the cooler based on the temperature of the stage.

10. The inspection apparatus of claim 4, wherein the drive mechanism is provided in a loader part disposed adjacent to an inspection part in which the stage is provided.

11. The inspection apparatus of claim 2, wherein the heat source is a drive mechanism, and the heat generation amount is adjusted by a standby power of the drive mechanism.

12. The inspection apparatus of claim 2, wherein the target temperature is 20 to 30 degrees C.

13. The inspection apparatus of claim 1, wherein the temperature controller is configured to reduce a heat generation amount of the heat source when the temperature of the stage is higher than a target temperature.

14. A temperature control device for controlling a temperature of a stage in an inspection apparatus for inspecting electrical characteristics of a plurality of devices formed on an inspection object by mounting the inspection object on the stage, comprising:
a temperature detector configured to detect the temperature of the stage;
a heat source provided separately from the stage;
a cooler configured to cool the stage; and
a temperature controller configured to control the heat source and the cooler based on the temperature of the stage detected by the temperature detector.

15. A temperature control method for controlling a temperature of an inspection apparatus for inspecting electrical characteristics of a plurality of devices formed on an inspection object by mounting the inspection object on a stage, the method comprising:
detecting a temperature of the stage; and
controlling a heat source provided separately from the stage and a cooler configured to cool the stage, based on the temperature of the stage.
